(19) United States
(12) Patent Application Publication
(10) Pub. No.: US 2011/0129686 A1
(43) Pub. Date: Jun. 2, 2011

(54) DEPOSITION METHOD, DEPOSITION APPARATUS, AND LAMINATED FILM

(75) Inventors: Hideo YAMADA, Kariya-city (JP); Kazushi ASAMI, Okazaki-city (JP); Masakazu SUGIYAMA, Yokohama-city (JP); Yukihiro SHIMOGAKI, Tokyo (JP); Takeshi MOMOSE, Tokyo (JP)

(73) Assignees: DENSO CORPORATION, Kariya-city (JP); The University of Tokyo, Tokyo (JP)

(21) Appl. No.: 12/876,333

(22) Filed: Sep. 7, 2010

(30) Foreign Application Priority Data
Nov. 30, 2009 (JP) 2009-272122

(51) Int. Cl. B32B 5/14; C23C 16/30; C23C 16/448; C23C 16/52; B32B 3/10; B32B 3/30; B32B 15/04

(52) U.S. Cl. 428/596; 427/248.1; 118/722; 428/610; 428/600

(57) ABSTRACT

In a deposition method of forming a compound layer including a metal and an oxide by a supercritical fluid deposition method, a first material for generating the metal and a second material for generating the oxide are supplied to a supercritical fluid. With an increase of a thickness of the compound layer, a ratio of a supplied amount of the first material with respect to a supplied amount of the second material is increased.

### CROSS REFERENCE TO RELATED APPLICATIONS

The present application is based on and claims priority to Japanese Patent Application No. 2009-272122 filed on Nov. 30, 2009, the contents of which are incorporated in their entirety herein by reference.

### BACKGROUND OF THE INVENTION

1. Field of the Invention

The present invention relates to a deposition method, a deposition apparatus, and a laminated film.

2. Description of the Related Art

In a case where a metal layer is formed by a supercritical fluid deposition method in order to form, for example, a penetrating electrode, it is necessary to form the metal layer on an insulating layer formed on a sidewall of a via.

Because when the metal layer is formed by a general hydrogen reduction method, the metal layer selectively grows only in a case where a base is a metal, it is difficult to form the metal layer directly on the insulating layer.

US 2008/107804A (corresponding to WO2005/118910A1) discloses a method in which after RuO is formed on an insulating layer, the RuO is reduced in hydrogen atmosphere into metal Ru, and a desired metal material is formed on the metal Ru. However, in the above-described technique, because an intermediate layer is the metal Ru, there is an issue that adhesion at an interface between the metal Ru and the insulating layer is low.

JP-A-7-54160 discloses, as shown in FIG. 6A, a method in which a conductive layer including an oxide is formed as an intermediate layer 405 on an insulating layer 403 on a surface of a substrate 401, and a metal layer 407 is formed on it by metal plating so as to improve adhesion of the metal layer 407. In the above-described technique, although a compound of the oxide and a conductor is used for the intermediate layer 405, as shown in FIG. 6B, a composition ratio is uniform. Thus, there is a limit on improving the adhesive between the insulating layer 403 and the metal layer 407 through the intermediate layer 405.

### SUMMARY OF THE INVENTION

In view of the foregoing problems, it is an object of the present invention to provide a deposition method, a deposition apparatus, and a laminated film that can improve an adhesion in a case where a metal layer is formed above an insulating layer through an intermediate layer.

According to a first aspect of the present invention, a deposition method of forming a compound layer including a metal and an oxide by a supercritical fluid deposition method includes supplying a first material for generating the metal and a second material for generating the oxide into a supercritical fluid, and the supplying includes increasing a ratio of a supplied amount of the first material with respect to a supplied amount of the second material with an increase of a thickness of the compound layer.

In the deposition method according to the first aspect, because the ratio of the supplied amount of the first material with respect to the supplied amount of the second material is increased with the increase of the thickness, a ratio of the metal in the compound layer can be increased in a thickness direction (in a direction where the thickness increases). Thus, when an insulating layer is formed on a side of the compound layer where a concentration of a metal component is low, a joint strength to the insulating layer is improved. In addition, when a metal layer is formed on a side where the concentration of the metal component is high, a joint strength to the metal layer is improved. As a result, in a case where the metal layer is formed above the insulating layer through the compound layer, the joint strength can be improved.

According to a second aspect of the present invention, a deposition method of forming a laminated film that includes a compound layer including a metal and an oxide and a metal layer, includes preparing a substrate having an insulating layer on a surface thereof, and forming a compound layer by a supercritical fluid deposition method by supplying a supercritical fluid, a first material for generating the metal in the compound layer, and a second material for generating the oxide in the compound layer to the substrate. The forming the compound layer includes increasing a ratio of a supplied amount of the first material with respect to a supplied amount of the second material with an increase of a thickness of the compound layer.

In the deposition method according to the second aspect, when the compound layer is formed, because the ratio of the supplied amount of the first material with respect to the supplied amount of the second material is increased with the increase of the thickness, a ratio of the metal in the compound layer can be increased in a thickness direction (in a direction where the thickness increases). Thus, when an insulating layer is formed on a side of the compound layer where a concentration of a metal component is low, a joint strength to the insulating layer is improved. In addition, when a metal layer is formed on a side where the concentration of the metal component is high, a joint strength to the metal layer is improved. As a result, in a case where the metal layer is formed above the insulating layer through the compound layer, the joint strength can be improved.

According to a third aspect of the present invention, a deposition apparatus for forming a compound layer including a metal and an oxide by a supercritical fluid deposition method includes a portion that supplies a first material for generating the metal and a second material for generating the oxide to a supercritical fluid, and a portion that changes a ratio of a supplied amount of the first material with respect to a supplied amount of the second material.

In the deposition apparatus according to the third aspect, the ratio of the supplied amount of the first material with respect to the supplied amount of the second material can be changed. Thus, for example, by increasing the ratio of the supplied amount of the first material with respect to the supplied amount of the second material with the increase of the thickness, a ratio of the metal in the compound layer can be increased in a thickness direction (in a direction where the thickness increases).

According to a fourth aspect of the present invention, a deposition apparatus for forming a laminated film by stacking a metal layer above an insulating layer on a surface of a substrate through a compound layer including a metal and an oxide, includes a portion that supplies a supercritical fluid, a first material for generating the metal in the compound layer, and a second material for generating the oxide in the compound layer to the substrate, and a portion that changes a ratio of a supplied amount of the first material with respect to a supplied amount of the second material.

In the deposition apparatus according to the fourth aspect, when the compound layer is formed, the ratio of the supplied amount of the first material with respect to the supplied amount of the second material can be changed. Thus, for example, by increasing the ratio of the supplied amount of the first material with respect to the supplied amount of the second material with the increase of the thickness, a ratio of the metal in the compound layer can be increased in a thickness direction (in a direction where the thickness increases).

According to a fifth aspect of the present invention, a deposition apparatus for forming a compound layer including a metal and an oxide by a supercritical fluid deposition method includes a portion that supplies a first material including a metal particulate or a material for generating a metal particulate and a second material for generating the oxide to a supercritical fluid, and a portion that changes a ratio of a supplied amount of the first material with respect to a supplied amount of the second material.

In the deposition apparatus according to the fifth aspect, the ratio of the supplied amount of the first material with respect to the supplied amount of the second material can be changed. Thus, for example, by increasing the ratio of the supplied amount of the first material with respect to the supplied amount of the second material with the increase of the thickness, a ratio of the metal in the compound layer can be increased in a thickness direction (in a direction where the thickness increases).

According to a sixth aspect of the present invention, a deposition apparatus for forming a laminated film by stacking a metal layer above an insulating layer on a surface of a substrate through a compound layer including a metal and an oxide, includes a portion that supplies a supercritical fluid, a first material including a metal particulate or a material for generating a metal particulate that becomes the metal in the compound layer and a second material for generating the oxide in the compound layer to the substrate, and a portion that changes a ratio of a supplied amount of the first material with respect to a supplied amount of the second material.

In the deposition apparatus according to the sixth aspect, when the compound layer is formed, the ratio of the supplied amount of the first material with respect to the supplied amount of the second material can be changed. Thus, for example, by increasing the ratio of the supplied amount of the first material with respect to the supplied amount of the second material with the increase of the thickness, a ratio of the metal in the compound layer can be increased in a thickness direction (in a direction where the thickness increases).

According to a seventh aspect of the present invention, a laminated film formed on a insulating surface, includes a compound layer formed on the insulating surface and including a metal and an oxide, and a metal layer formed on the compound layer, and a metal concentration of the compound layer increases from a insulating surface side toward a metal layer side.

In the laminated film according to the seventh aspect, the metal concentration of the compound layer increases from the insulating surface side toward the metal layer side. Thus, a joint strength of a side of the compound layer where the concentration of the metal component is low and the insulating layer is improved and a joint strength of a side of the compound layer where the concentration of the metal component is high and the metal layer is increased. As a result, a joint strength of the metal layer to the substrate can be improved.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1A is a cross-sectional view showing a laminated film according to a first embodiment of the present invention;

FIG. 1B is a diagram showing concentration gradients of a metal and an oxide in an intermediate layer in the laminated film according to the first embodiment;

FIG. 2 is a diagram showing a deposition apparatus according to the first embodiment of the present invention;

FIG. 3 is a diagram showing a deposition apparatus according to a second embodiment of the present invention;

FIG. 4 is a diagram showing a deposition apparatus according to a third embodiment of the present invention;

FIG. 5A is a cross-sectional view showing a laminated film according to a fourth embodiment of the present invention;

FIG. 5B is a diagram showing concentration gradients of a metal and an oxide in an intermediate layer in the laminated film according to the fourth embodiment;

FIG. 6A is a cross-sectional view showing a laminated film according to a prior art; and

FIG. 6B is a diagram showing concentration gradients of a metal and an oxide in an intermediate layer in the laminated film according to the prior art.

### DETAILED DESCRIPTION OF THE PREFERRED EMBODIMENTS

### First Embodiment

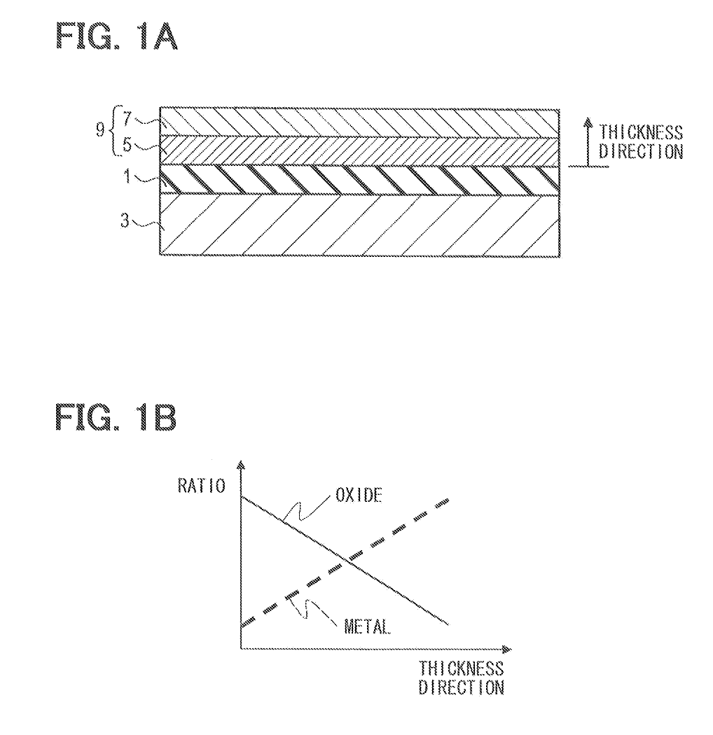

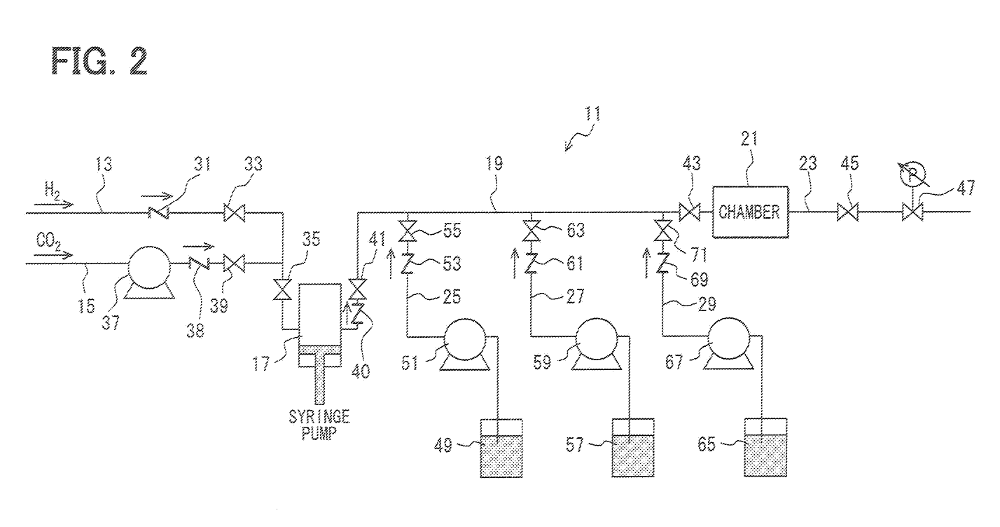

A deposition apparatus 11 used for forming a laminated film according to a first embodiment of the present invention will be described with reference to FIG. 2. The deposition apparatus according to the present embodiment is used for forming a laminated film 9 as shown in FIG. 1A by using a supercritical fluid deposition method. The laminated film 9 is formed on a substrate 3 having an insulating layer 1 on a surface thereof and includes an intermediate layer 5 and a metal layer 7 formed on the intermediate layer 5. The intermediate layer 5 is a compound layer including a metal and an oxide.

Here, the supercritical fluid deposition method is a technique in which a material dissolved in a fluid in a supercritical state (supercritical fluid) is deposit, for example, on a surface of a substrate and thereby forming a layer. The supercritical state is a state that exceeds critical points of a temperature and a pressure and, in the present application, includes a subcritical state. The subcritical state is less than the critical points and is in a region close to the critical points (in the supercritical deposition, the subcritical state shows a phenomenon similar to the critical state).

As shown in FIG. 2, the deposition apparatus 11 according to the present embodiment includes a first pipeline 13, a second pipeline 15, a syringe pump 17, a third pipeline 19, a chamber 21, and a fourth pipeline 23 from an upstream side of a flow channel. To the third pipeline 19, a fifth pipeline 25, a sixth pipeline 27, and a seventh pipeline 29 are coupled.

The first pipeline 13 is a pipeline for supplying hydrogen gas (H₂) to the syringe pump 17. On the first pipeline 13, a check valve 31 and two hand valves 33 and 35 are disposed from the upstream side. The hand valves 33 and 35 can control an opening and closing of the pipeline.

The second pipeline 15 is a pipeline for supplying carbon dioxide gas (CO₂) that becomes a supercritical fluid to the syringe pump 17 through the first pipeline 13. On the second pipeline 15, a pump 37, a check valve 38, and a hand valve 39 are disposed. The pump 37 applies pressure to the carbon dioxide gas and supplies the carbon dioxide gas to the syringe pump 17. The second pipeline 15 is coupled to a portion of the first pipeline 13 between the hand valves 33 and 35.

The syringe pump 17 mixes and pressurizes the hydrogen gas and the carbon dioxide gas supplied to the syringe pump 17 and supplies the mixed gas to the third pipeline 19. The third pipeline 19 is a pipeline for supplying the mixed gas to the chamber 21. On the third pipeline 19, the check valve 40 and the hand valves 41 and 43 are disposed.

The chamber 21 is a reaction chamber for forming the laminated film 9 on the surface of the substrate. The fourth pipeline 23 is a pipeline for discharging gas in the chamber 21. On the fourth pipeline 23, a hand valve 45 and an automatic pressure control valve 47 are disposed from the upstream side. The automatic pressure control valve 47 is used for controlling a pressure in the chamber 21 to a predetermined pressure.

The fifth pipeline 25 is a pipeline for supplying a first material for generating the metal in the intermediate layer 5 to the chamber 21 through the third pipeline 19. On the fifth pipeline 25, a first container 49 for housing the first material, a pump 51 for supplying the first material to the third pipeline 19, a check valve 53, and a hand valve 55 are disposed from the upstream side.

The sixth pipeline 27 is a pipeline for supplying a first material for generating a metal oxide in the intermediate layer 5 to the chamber 21 through the third pipeline 19. On the sixth pipeline 27, a second container 57 for housing the second material, a pump 59 for supplying the second material to the third pipeline 19, a check valve 61, and a hand valve 63 are disposed from the upstream side.

The seventh pipeline 29 is a pipeline for supplying a third material for generating the metal layer to the chamber 21 through the third pipeline 19. On the seventh pipeline 29, a third container 65 for housing the third material, a pump 67 for supplying the third material to the third pipeline 19, a check valve 69, and a hand valve 71 are disposed from the upstream side.

The fifth pipeline 25, the sixth pipeline 27, and the seventh pipeline 29 are coupled with the third pipeline 19 between the hand valves 41 and 43.

A deposition method performed with the deposition apparatus 11 will be described. First, the substrate 3 is disposed in the chamber 21 and the chamber 21 is closed. The substrate 3 is a silicon substrate and has the insulating layer 1 made of silicon oxide on the surface thereof. The chamber 21 allows inflow and outflow of gas.

Next, the pump 37 is operated, and the carbon oxide gas is supplied to the whole apparatus (that is, an inside of the apparatus such as the pipelines and the chambers: an inside of the flow channel) through the second pipeline 15 at a flow rate of 10 ml/min. At this time, the hand valves 39, 35, 41, 43, 45 are opened and the hand valves 33, 55, 63, and 71 are closed.

Then, the whole apparatus is maintained at 50° C. with a heater (not shown) attached to the pipelines, and the substrate 3 is maintained at 200° C. with a heater (not shown) attached in the vicinity of the substrate 3. In addition, a pressure of the whole apparatus is maintained at 15 MPa with the automatic pressure control valve 47.

Next, the hand valve 33 is opened and hydrogen gas of 1 MPa at 25° C. is supplied to the syringe pump 17 at a flow rate of 1 ml/min. Then, carbon dioxide at 25° C. is supplied at a flow rate of 10 ml/min until an inside of the syringe pump 17 becomes 10 MPa, and the hand valve 35 is closed. After that, the whole of the syringe pump 17 is heated with a heater (not shown), and a mixed fluid is provided by mixing the hydrogen gas and the carbon dioxide gas while maintaining the inside of the syringe pump 17 at 50° C. and 15 MPa. When the mixed fluid is formed, the inside of the syringe pump 17 is in a sealed state.

The carbon oxide in the mixed gas is in a supercritical state that exceeds critical points (pressure of 7.38 Mpa and temperature of 31.1° C.). The composition ratio (molar ratio) of the mixed fluid is H₂:CO₂=1:9.

As materials for forming the laminated film 9, the first material for generating the metal in the intermediate layer 5, the second material for generating the metal oxide in the intermediate layer 5, and the third material for generating the metal in the metal layer 7 are prepared.

As the first material, a solution in which Cu(tmhd)₂ (chemical formula: C₂₂H₄₀CuO₄) is dissolved in acetone as solvent at a ratio of 780 mg to 100 ml is prepared.

As the second material, a solution in which Mn(pmcp)₂ (chemical formula: C₂₀H₃₀Mn) is dissolved in acetone as solvent at a ratio of 588 g to 100 ml is prepared. As the third material, a solution in which Cu(tmhd)₂ (chemical formula: C₂₂H₄CuO₄) is dissolved in acetone as solvent at a ratio of 780 mg to 100 ml is prepared.

As the third material, a solution in which Ru(tmhd)₃ (chemical formula: C₃₃H₅₇O₆Ru) is dissolved in acetone as solvent at a ratio of 1173 mg to 100 ml may also be used.

Then, the mixed fluid, the first material, and the second material are supplied to the chamber 21 for 5 minutes. At this time, the hand valves 55 and 63 are opened and the pumps 51 and 59 are operated.

The temperature of the whole apparatus is maintained at 50° C., the temperature of the substrate is maintained at 200° C., and the pressure is maintained at 15 MPa with the automatic pressure control valve 47. The mixed fluid is supplied at a constant flow rate of 1.25 ml/min. The first material is supplied at a constant flow rate of 0.7 ml/min. The flow rate of the second material is changed from 0.7 ml/min at a constant changing amount of −0.08 ml/min (in such a manner that the flow rate gradually decreases), and the flow rate of the second material becomes 0.3 ml/min after 5 minutes.

In other words, a ratio of a supplied amount of the first material with respect to a supplied amount of the second material (the first material/the second material) is changed from 1 to 2.3 for 5 minutes at a constant changing amount. That is, the supplied ratio of the first material is continuously increased with time.

The ratio of the supplied amount of the first material with respect to the supplied amount of the second material is controlled by adjusting the supplied amount of respective materials with the pumps 51 and 59 (specifically, by adjusting rotation numbers of the pumps 51 and 59). The supplied amount (flow rate) of the mixed fluid is set by controlling the syringe pump 17. When the mixed fluid is supplied, an inflow side is closed and an outflow side is opened.

After a predetermined time (for example, after 5 minutes) has elapsed from starting the supply of the materials, the supply of the first material and the second material is stopped by closing the hand valve 55 and 63 and stopping the pumps 51 and 59.

Accordingly, the intermediate layer 5 having the thickness of 50 nm is formed. A concentration gradient of the metal (Cu) in the intermediate layer 5 increases by 1.5% per 1 nm in a thickness direction (in a direction where the thickness increases). On the other hand, a concentration gradient of the metal oxide (MnO and MnO₂) in the intermediate layer 5 decreases by 1.5% per 1 nm in the thickness direction.

A forming process of the intermediate layer 5 will be described in detail. Cu(tmhd)₂ in the first material supplied to the carbon dioxide gas in the supercritical state is reduced with hydrogen as a reducing agent and is deposited as the metal (Cu) in the intermediate layer 5. Mn(pmcp)₂ in the second material supplied to the carbon dioxide gas in the supercritical state is oxidized with carbon dioxide and is deposited as the metal oxide (manganese oxide: MnO₂, MnO) in the intermediate layer 5.

Because Cu in the intermediate layer 5 is a material that is more difficult to be oxidized than Mn that forms the metal oxide, Cu and the oxide of Mn are deposited in the intermediate layer 5. As an indicator of easy substance to be oxidized, for example, an Ellingham diagram is known. The lower substances are located in the Ellingham diagram, that is, the lower standard reaction Gibbs energy of oxide the substances have, the easier the substances are oxidized.

After forming the intermediate layer 5, the mixed fluid and the third material are supplied to the chamber 21 for 10 minutes. At this time, the hand valve 71 is opened and the pump 67 is operated. The temperature of the whole apparatus is maintained at 50° C., the temperature of the substrate is maintained at 200° C., and the pressure is maintained at 15 MPa with the automatic pressure control valve 47.

The mixed fluid is supplied at a constant flow rate of 1.25 ml/min and the third material is supplied at a constant flow rate of 0.7 ml/min. The supplied amount of the third material is controlled by adjusting the rotation number of the pump 67.

After a predetermined time (for example, after 10 minutes) has elapsed from starting the supply of the third material, the supply of the mixed fluid and the third material is stopped. When the supply of the third material is stopped, the hand valve 71 is closed and the pump 67 is stopped.

Accordingly, the metal layer 7 having a thickness of 10 nm is formed. Cu(tmhd)₂ in the third material supplied to the carbon dioxide gas in the supercritical state is reduced with hydrogen as a reducing agent and is deposited as the metal (Cu) for forming the metal layer 7.

As described above, in the present embodiment, when the intermediate layer 5 is formed on the insulating layer 1 on the surface of the substrate 3 by the supercritical fluid deposition method, the ratio of the supplied amount of the first material with respect to the supplied amount of the second material is gradually increased with time. Thus, as shown in FIG. 1B, the metal concentration in the intermediate layer 5 increases at a constant gradient from the insulating layer 1 side toward the metal layer 7 side. In addition, the metal oxide concentration decreases at a constant gradient inversely (complementarily) with the metal concentration.

Thus, the intermediate layer 5 has a high joint strength to the insulating layer 1 and has a high joint strength to the metal layer 7. In other words, the laminated film 9 including the intermediate layer 5 and the metal layer 7 has a high joint strength to the insulating layer 1 (that is, the substrate 3).

### Second Embodiment

A second embodiment of the present invention will be described below. In the present embodiment, as a material for forming an intermediate layer, a metal particulate is used.

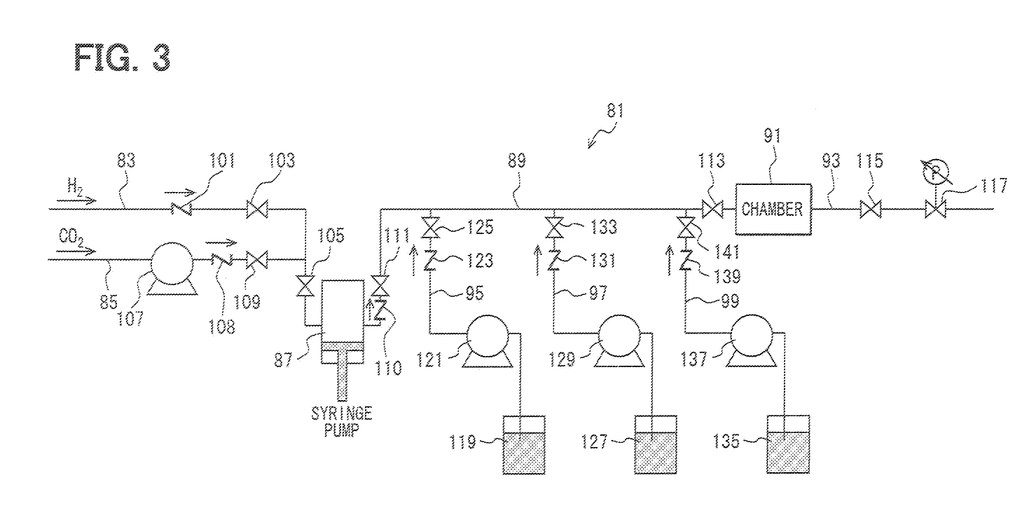

A deposition apparatus 81 used for forming a laminated film according to the present embodiment will be described with reference to FIG. 3. Because this deposition apparatus is substantially similar to the deposition apparatus 11 according to the first embodiment, this deposition apparatus will be simply described.

The deposition apparatus 81 according to the present embodiment includes a first pipeline 83, a second pipeline 85, a syringe pump 87, a third pipeline 89, a chamber 91, and a fourth pipeline 93 from an upstream side of a flow channel. To the third pipeline 89, a fifth pipeline 95, a sixth pipeline 97, and a seventh pipeline 99 are coupled.

On the first pipeline 83, a check valve 101 and two hand valves 103 and 105 are disposed. On the second pipeline 85, a pump 107, a check valve 108, and a hand valve 109 are disposed. On the third pipeline 89, a check valve 110, and hand valves 111 and 113 are disposed.

On the fourth pipeline 93, a hand valve 115 and an automatic pressure control valve 117 are disposed. On the fifth pipeline 95, a first container 119 for housing a first material for generating a metal in an intermediate layer 5, a pump 121, a check valve 123, and a hand valve 125 are disposed.

On the sixth pipeline 97, a second container 127 for housing a second material for generating a metal oxide in the intermediate layer 5, a pump 129, a check valve 131, and a hand valve 133 are disposed.

On the seventh pipeline 99, a third container 135 for housing a third material for generating a metal in a metal layer 7, a pump 137, a check valve 139, and a hand valve 141 are disposed.

A deposition method performed with the deposition apparatus 81 will be described below. For each layer, the same reference numbers are used as FIG. 1A.

First, a substrate 3 is disposed in the chamber 91 and the chamber 91 is closed. The substrate 3 is a silicon substrate and has an insulating layer 1 made of silicon oxide on the surface thereof. Next, the pump 107 is operated, and the carbon oxide gas is supplied to the whole apparatus (that is, an inside of the apparatus such as the pipelines and the chambers) through the second pipeline 85 at a flow rate of 10 ml/min. At this time, the hand valves 109, 105, 111, 113, 115 are opened and the hand valves 103, 125, 133, and 141 are closed.

Then, the whole apparatus is maintained at 50° C. with a heater (not shown) attached to the pipelines, and the substrate 3 is maintained at 200° C. with a heater (not shown) attached in the vicinity of the substrate 3. In addition, a pressure of the whole apparatus is maintained at 15 MPa with the automatic pressure control valve 117.

Next, the hand valve 103 is opened and hydrogen gas of 1 MPa at 25° C. is supplied to the syringe pump 87 at a flow rate of 1 ml/min. Then, carbon dioxide at 25° C. is supplied at a flow rate of 10 ml/min until an inside of the syringe pump 17 becomes 10 MPa, and the hand valve 105 is closed. Then, the whole of the syringe pump 87 is heated with a heater (not shown), and a mixed fluid is provided by mixing the hydrogen gas and the carbon dioxide gas while maintaining the inside of the syringe pump 87 at 50° C. and 15 MPa. The composition ratio (molar ratio) of the mixed fluid is H₂:CO₂=1:9.

As materials for forming a laminated film 9, the first material, the second material, and the third material are prepared. In the present embodiment, as the first material, a colloidal solution in which Au nano particles having a particle size of 5 nm are dispersed in water as solvent at a metal concentration of 4 weight % is prepared.

As the second material, a solution in which Mn(pmcp)₂ (chemical formula: C₂₀H₃₀Mn) is dissolved in acetone as solvent at a ratio of 588 g to 100 ml is prepared. As the third material, a solution in which Cu(tmhd)₂ (chemical formula: C₂₂H₄₀CuO₄) is dissolved in acetone as solvent at a ratio of 780 mg to 100 ml is prepared.

As the third material, a solution in which Ru(tmhd)₃ (chemical formula: C₃₃H₅₇O₆Ru) is dissolved in acetone as solvent at a ratio of 1173 mg to 100 ml may also be used.

The mixed fluid, the first material, and the second material are supplied to the chamber 91 for 5 minutes. The temperature of the whole apparatus is maintained at 50° C., the temperature of the substrate is maintained at 200° C., and the pressure is maintained at 15 MPa with the automatic pressure control valve 117.

The mixed fluid is supplied at a constant flow rate of 1.25 ml/min. The first material is supplied at a constant flow rate of 1 ml/min. The flow rate of the second material is changed from 0.7 ml/min at a constant changing amount of −0.08 ml/min, and the flow rate of the second material becomes 0.3 ml/min after 5 minutes.

In other words, a ratio of a supplied amount of the first material with respect to a supplied amount of the second material is changed from 1.4 to 3.3 for 5 minutes at a constant changing amount. That is, the ratio of the supplied amount of the first material with respect to the supplied amount of the second material is continuously increased with time.

After a predetermined time (for example, after 5 minutes) has elapsed from starting the supply of the materials, the supply of the first material and the second material is stopped. Accordingly, the intermediate layer 5 having a thickness of 50 nm is formed. A concentration gradient of the metal in the intermediate layer 5 increases by 1.5% per 1 nm in the thickness direction.

After forming the intermediate layer 5, the mixed fluid and the third material are supplied to the chamber 91 for 10 minutes. At this time, the hand valve 141 is opened and the hand valves 125 and 133 are closed. The temperature in the chamber 91 is 200° C. and the pressure is control to be 15 MPa with the automatic pressure control valve 117.

The mixed fluid is supplied at a constant flow rate of 1.25 ml/min. The third material is supplied at a constant flow rate of 0.7 ml/min. After a predetermined time (for example, after 10 minutes) has elapsed from starting the supply of the third material, the supply of the mixed fluid and the third material is stopped. Accordingly, the metal layer 7 having a thickness of 100 nm is formed.

Also in the present embodiment, when the intermediate layer 5 is formed on a surface of the insulating layer 1 on the surface of the substrate by the supercritical fluid deposition method, the ratio of the supplied amount of the first material with respect to the supplied amount of the second material is gradually increased with time. Thus, the metal concentration in the intermediate layer 5 increases at a constant gradient from the insulating layer 1 side toward the metal layer 7 side.

Thus, the intermediate layer 5 has a high joint strength to the insulating layer 1 and has a high joint strength to the metal layer 7. In other words, the laminated film 9 including the intermediate layer 5 and the metal layer 7 has a high joint strength to the insulating layer 1 (that is, the substrate 3).

### Third Embodiment

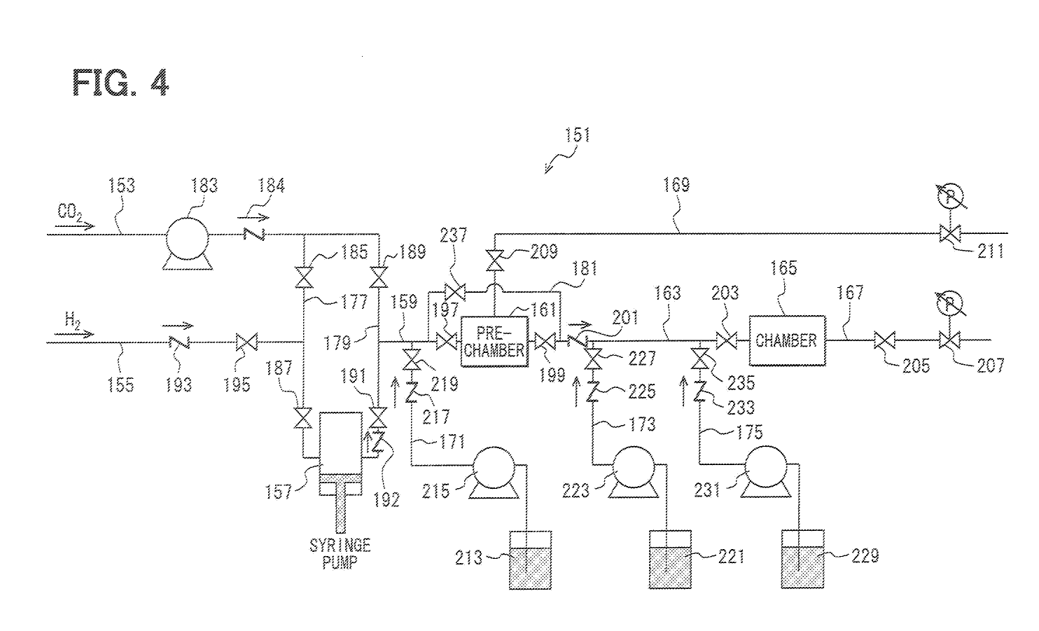

A third embodiment of the present invention will be described below. First, a deposition apparatus 151 used for forming a laminated film according to the present embodiment will be described with reference to FIG. 4. The deposition apparatus 151 according to the present embodiment includes a first pipeline 153, a second pipeline 155, a syringe pump 157, a third pipeline 159, a pre-chamber 161, a fourth pipeline 163, a chamber 165, and a fifth pipeline 167 from an upstream side of a flow channel.

The pre-chamber 161 is coupled with a sixth pipeline 169. The third pipeline 159 is coupled with a seventh pipeline 171. The fourth pipeline 163 is coupled with an eighth pipeline 173 and a ninth pipeline 175. First and second bypass pipeline 177 and 179 diverging from the first pipeline 153 are respectively coupled with openings on an upstream side and a downstream side of the syringe pump 157.

Furthermore, in order to bypass the pre-chamber 161, a bypass pipeline 181 coupling the first pipeline 159 and the fourth pipeline 163 is provided.

The first pipeline 153 is a pipeline for supplying carbon dioxide gas (CO₂) that becomes a supercritical fluid to the syringe pump 157. On the first pipeline 153, a pump 183 and a check valve 184 are disposed. On the first bypass pipeline 177, hand valves 185 and 187 are disposed. On the second bypass pipeline 179, hand valves 189 and 191 and a check valve 192 are disposed.

The second pipeline 155 is a pipeline for supplying hydrogen gas (H₂) to the syringe pump 157. On the second pipeline 155, a check valve 193 and a hand valve 195 are disposed. The second pipeline 155 is coupled to a portion of the first bypass pipeline 177 between the hand valves 185 and 187.

The third pipeline 159 is a pipeline for coupling a portion of the second bypass line 170 between the hand valves 189 and 191 and the pre-chamber 161. On the third pipeline 159, a hand valve 197 is disposed. The pre-chamber 161 is a reaction chamber for forming a metal particulate by thermal reaction.

The fourth pipeline 163 is a pipeline for coupling the pre-chamber 161 and the chamber 165. On the fourth pipeline 163, a hand valve 199, a check valve 201, and a hand valve 203 are disposed. The chamber 165 is a reaction chamber for forming the laminated film 9 on a surface of a substrate.

The fifth pipeline 167 is a pipeline for discharging gas in the chamber 165. On the fifth pipeline 167, a hand valve 205 and an automatic pressure control valve 207 are disposed. The automatic pressure control valve 207 is used for controlling a pressure in the chamber 165 to a predetermined pressure.

The sixth pipeline 169 is a pipeline for discharging gas in the pre-chamber 161. On the sixth pipeline 169, a hand valve 209 and an automatic pressure control valve 211 are disposed. The automatic pressure control valve 211 is used for controlling a pressure in the pre-chamber 161 to a predetermined pressure.

The seventh pipeline 171 is a pipeline for supplying a first material to the pre-chamber 161 through the third pipeline 159. On the seventh pipeline 171, a first container 213 for housing a first material, a pump 215, a check valve 217, and a hand valve 219 are disposed. The seventh pipeline 171 is coupled to a portion of the third pipeline 159 on the upstream side of the hand valve 197.

The eighth pipeline 173 is a pipeline for supplying a second material to the chamber 165 through the fourth pipeline 163. On the eighth pipeline 173, a second container 221 for housing a second material, a pump 223, a check valve 225, and a hand valve 227 are disposed. The eighth pipeline 173 is coupled to a portion of the fourth pipeline 163 between the check valve 201 and the hand valve 203.

The ninth pipeline 175 is a pipeline for supplying a third material to the chamber 165 through the fourth pipeline 163. On the ninth pipeline 175, a third container 229 for housing a third material, a pump 231, a check valve 233, and a hand valve 235 are disposed. The ninth pipeline 175 is coupled to a portion of the fourth pipeline 163 between the check valve 201 and the hand valve 203.

The bypass pipeline 181 is a pipeline for coupling the third pipeline 159 on the upstream side of the hand valve 197 and the fourth pipeline 163 between the hand valve 199 and the check valve 201. On the bypass pipeline 181, a hand valve 237 is disposed.

A deposition method performed with the deposition apparatus 151 will be described. First, a substrate 3 is disposed in the chamber 165 and the chamber 165 is closed. The substrate 3 is a silicon substrate and has an insulating layer 1 made of silicon oxide on the surface thereof.

The pump 183 is operated, and carbon oxide gas is supplied to the whole apparatus (that is, an inside of the apparatus such as the pipeline, the pre-chamber and the chamber) through the first pipeline 153 at a flow rate of 10 ml/min. At this time, the hand valves 185, 187, 191, 197, 199, 203, 205, 209, and 237 are opened and the hand valves 195, 219, 227, and 235 are closed.

Then, the whole apparatus is maintained at 50° C. with a heater (not shown) attached to the pipelines, and the substrate 3 is maintained at 200° C. with a heater (not shown) attached in the vicinity of the substrate 3. In addition, a pressure of the whole apparatus is maintained at 15 MPa with the automatic pressure control valve 207.

Next, the hand valve 195 is opened and hydrogen gas of 1 MPa at 25° C. is supplied to the syringe pump 157 at a flow rate of 1 ml/min, and the check valve 187 is closed. Then, carbon dioxide at 25° C. is supplied at a flow rate of 10 ml/min until an inside of the syringe pump 157 becomes 10 MPa. The whole of the syringe pump 157 is heated with a heater (not shown), and a mixed fluid is formed by mixing the hydrogen gas and the carbon dioxide gas while maintaining the inside of the syringe pump 157 at 50° C. and 15 MPa. The composition ratio (molar ratio) of the mixed fluid is H₂:CO₂=1:9.

As materials for forming a laminated film 9, the first material, the second material, and the third material are prepared. As the first material, a solution in which Cu(acac)₂ (chemical formula: C₁₀H₁₄CuO₄) is dissolved in acetone as solvent at a ratio of 473 mg to 100 ml is prepared.

As the second material, a solution in which Mn(pmcp)₂ (chemical formula: C₂₀H₃₀Mn) is dissolved in acetone as solvent at a ratio of 588 g to 100 ml is prepared. As the third material, a solution in which Cu(tmhd)₂ (chemical formula: C₂₂H₄OCuO₄) is dissolved in acetone as solvent at a ratio of 780 mg to 100 ml is prepared.

As the third material, a solution in which Ru(tmhd)₃ (chemical formula: C₃₃H₅₇O₆Ru) is dissolved in acetone as solvent at a ratio of 1173 mg to 100 ml may also be used.

The first material is supplied to the pre-chamber 161 for 5 minutes. Both of carbon dioxide gas and the first material are supplied at a constant flow rate of 2 ml/min. At this time, the hand valves 189, 197, 209, and 219 are opened and the hand valves 185, 191, 199, and 237 are closed. The pressure is maintained at 15 MPa with the automatic pressure control valve 211.

Next, the pre-chamber 161 is heated to 250° C., and Cu particles having an average particle size of 10 nm are generated from Cu(acac)₂ by thermal reaction. After that, the mixed fluid, the generated Cu particles, and the second material are supplied into the chamber 165 for 5 minutes. Forming method of the mixed gas is similar to the first embodiment. At this time, the hand valves 185, 195, 187, 191, 197, 199, 227, 203, and 205 are opened and the hand valves 189, 219, 237, 209, and 235 are closed. The temperature of the whole apparatus is maintained at 50° C. and the temperature of the substrate is maintained at 200° C. The pressure is maintained at 15 MPa with the automatic pressure control valve 207.

The mixed fluid is supplied at a constant flow rate of 1.25 ml/min. The Cu particles are carried away by the mixed gas by a predetermined amount (for example, a predetermined weight %) The flow rate of the second material is changed from 0.7 ml/min at a constant changing amount of −0.08 ml/min, and the flow rate of the second material becomes 0.3 ml/min after 5 minutes.

That is, the ratio of the supplied amount of the first material with respect to the supplied amount of the second material is continuously increased with time. After a predetermined time (for example, after 5 minutes) has elapsed from starting the supply of the materials, the supply of the first material and the second material is stopped. Accordingly, the intermediate layer 5 having a thickness of 50 nm is formed. A concentration gradient of the metal in the intermediate layer 5 increases by 1.5% per 1 nm in the thickness direction.

After forming the intermediate layer 5, the mixed fluid and the third material are supplied to the chamber 165 for 10 minutes. At this time, the hand valves 191, 203, 205, 235, and 237 are opened and the hand valves 185, 187, 189, 195, 197, 209, 219, and 227 are closed. The temperature in the chamber 165 is maintained at 200° C. and the pressure is maintained at 15 MPa with the automatic pressure control valve 207.

The mixed fluid is supplied at a constant flow rate of 1.25 ml/min. The third material is supplied at a constant flow rate of 0.7 ml/min. Then, after a predetermined time (for example, after 10 minutes) has elapsed from starting the supply of the third material, the supply of the mixed fluid and the third material is stopped. Accordingly, the metal layer 7 having a thickness of 100 nm is formed.

Also in the present embodiment, when the intermediate layer 5 is formed on a surface of the insulating layer 1 on the surface of the substrate by the supercritical fluid deposition method, the ratio of the supplied amount of the first material with respect to the supplied amount of the second material is gradually increased with time. Thus, the metal concentration in the intermediate layer 5 increases at a constant gradient from the insulating layer 1 side toward the metal layer 7 side.

Thus, the intermediate layer 5 has a high joint strength to the insulating layer 1 and has a high joint strength to the metal layer 7. In other words, the laminated film 9 including the intermediate layer 5 and the metal layer 7 has a high joint strength to the insulating layer 1 (that is, the substrate 3).

### Fourth Embodiment

A fourth embodiment of the present invention will be described below. In the present embodiment, a ratio of the supplied amount of the first material with respect to the supplied amount of the second material is changed in a stepwise manner.

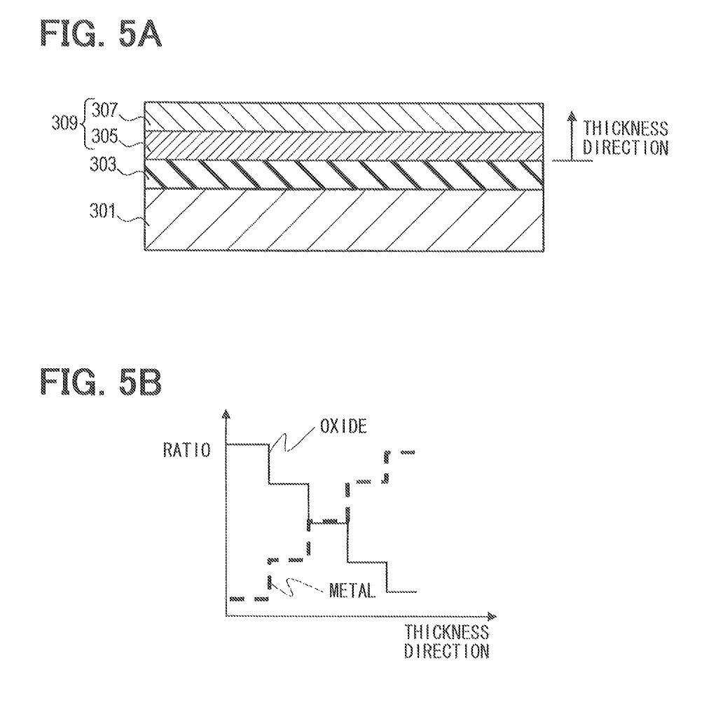

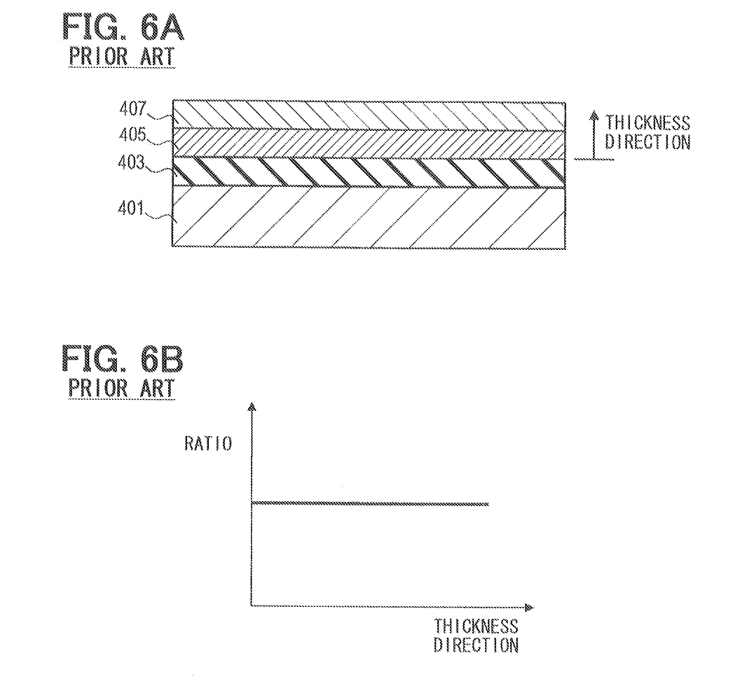

As shown in FIG. 5A, when an intermediate layer 305 is formed on an insulating layer 303 on a surface of a substrate 301, a flow rate of the second material is change from 0.7 ml/min by −0.08 ml/min at 1 minute intervals.

Accordingly, as shown in FIG. 5B, the metal concentration of the intermediate layer 305 is changed from the insulating layer 303 side toward the metal layer 307 by a constant concentration (for example, 15%) per a constant thickness (for example, 10 nm) in a stepwise manner. The metal oxide concentration decreases inversely (complementarily) with the metal concentration in a stepwise manner.

Thus, the intermediate layer 305 has a high joint strength to the insulating layer 303 and has a high joint strength to the metal layer 307. In other words, the laminated film 309 including the intermediate layer 305 and the metal layer 307 has a high joint strength to the insulating layer 303 (that is, the substrate 301).

### Fifth Embodiment

A fifth embodiment of the present invention will be described below. In the present embodiment, a trench having an aspect ratio of greater than or equal to 100 is provided on a surface of a silicon substrate. The trench has a depth of 50 μm, an opening width of 0.5 μm, and an aspect ratio of 100, for example. Then, an insulating layer of 0.5 μm is formed on the surface of the substrate by thermal oxidization, and a laminated film is formed on the surface of the substrate in a manner similar to the first embodiment.

Alternatively, a through hole having an aspect ratio of greater than or equal to 100 is provided in a silicon substrate. The through hole has a depth (a thickness of the substrate) of 625 μm, a diameter of 5 μm, and an aspect ratio of 125, for example. Then, on the surface of the substrate, a laminated film is formed in a manner similar to the first embodiment.

Also in the present embodiment, effects similar to the first embodiment can be obtained.

### Sixth Embodiment

A sixth embodiment of the present invention will be described below. In the present embodiment, concentration gradients of a metal and a metal oxide in an intermediate layer are different from those of the first embodiment.

In the present embodiment, when the intermediate layer is formed, the mixed fluid is supplied at a constant flow rate of 1.25 ml/min. The first material is supplied at a constant flow rate of 0.7 ml/min. The flow rate of the second material is changed from 0.7 ml/min at a constant changing amount of −0.05 ml/min so that the flow rate becomes 0.45 ml/min after 5 minutes. Other manufacturing conditions for forming the intermediate layer are similar to the first embodiment.

Accordingly, the intermediate layer having a thickness of 50 nm is formed. The metal concentration in the intermediate layer increases by 10% per 10 nm in the thickness direction of the intermediate layer. On the other hand, the concentration gradient of the metal oxide decreases by 10% per 10 nm in the thickness direction. Also in the present embodiment, effects similar to the first embodiment can be obtained.

### Other Embodiments

Although the present invention has been fully described in connection with the preferred embodiments thereof with reference to the accompanying drawings, it is to be noted that various changes and modifications will become apparent to those skilled in the art.

For example, a material of the insulating layer is not limited to silicon oxide and may also be silicon nitride (SiN). An oxide that forms the intermediate layer is not limited to the metal oxide and may also be silicon oxide.

The metal oxide that forms the intermediate layer is not limited to manganese oxide (MnO₂, MnO) and may also be titanium oxide (TiO₂), aluminum oxide (Al₂O₃), hafnium oxide (HfO), tantalum oxide (Ta₂O₅), or strontium titanate (SrTiO₃).

In this case, as a material for generating each oxide, Ti(O.i-Pr)₂(dpm)₂ (chemical formula: C₂₈H₅₂O₆Ti), Al(hfac)₃ (chemical formula: C₁₅H₃F₁₈O₃Al), Hf(tmhd)₄ (chemical formula: C₄₄H₈₀O₈Hf), Ta(i-OC₃H₇)₅ (chemical formula: H₁₅H₃₅O₅Ta), Sr(tmhd)₂ (chemical formula: C₂₂H₄₀O₄Sr) may be used.

A metal that forms the intermediate layer (a metal other the metal that forms the metal oxide) is not limited to copper (Cu) and may also be nickel (Ni) or ruthenium (Ru). A material that generates copper is not limited to Cu(tmhd)₂ and may also be Cu(acac)₂ or Cu(hfac)₂.

A material that becomes other metal, NiCp₂ or Ru(thhd)₃ may also be used. Wherein, Cp means bis-cyclopentadienyl. A metal that forms the metal particulate is not limited to gold and may also be copper, nickel, or ruthenium. The third material for forming the metal layer may also be Cu(Hfac)₂ (chemical formula: C₁₀H₂F₁₂CuO₂) or Ru(tmhd)₃ (chemical formula: C₃₃H₅₇O₆Ru).

The deposition apparatus according to each of the above-described embodiments is manually operated as an example. For example, electromagnetic control valves (opening and closing valve) may be used instead of hand valves, timings of opening and closing and degrees of opening and closing of the electromagnetic control valve may be controlled with an electronic control device, and thereby a laminated film may be formed automatically. The operations of the pumps may also be controlled with an electronic control device.

A method of adjusting the metal concentration is not limited to a method that includes adjusting a supplied amount with a pump and may also be a method that includes performing a duty ratio control of an electromagnetic control valve and adjusting an opening degree of the electromagnetic control valve.

1. A deposition method of forming a compound layer including a metal and an oxide by a supercritical fluid deposition method, the method comprising
supplying a first material for generating the metal and a second material for generating the oxide to a supercritical fluid, wherein the supplying includes increasing a ratio of a supplied amount of the first material with respect to a supplied amount of the second material with an increase of a thickness of the compound layer.

2. A deposition method of forming a laminated film that includes a compound layer including a metal and an oxide, and a metal layer, the deposition method comprising
preparing a substrate having an insulating layer on a surface thereof, and
forming a compound layer by a supercritical fluid deposition method by supplying a supercritical fluid, a first material for generating the metal in the compound layer, and a second material for generating the oxide in the compound layer to the substrate, wherein
the forming the compound layer includes increasing a ratio of a supplied amount of the first material with respect to a supplied amount of the second material with an increase of a thickness of the compound layer.

3. The deposition method according to claim 1, further comprising
mixing the supercritical fluid with a reducing agent, and
depositing the metal in the compound layer by reducing the first material with the reducing agent.

4. The deposition method according to claim 3, wherein
the reducing agent is hydrogen.

5. The deposition method according to claim 1, wherein
the supplying includes increasing the ratio of the supplied amount of the first material with respect to the supplied amount of the second material continuously or in a stepwise manner with the increase of the thickness of the compound layer.

6. The deposition method according to claim 1, wherein the supercritical fluid includes an oxidizing agent component, the deposition method further comprising
depositing the oxide in the compound layer by oxidizing the second material with the oxidizing agent component.

7. The deposition method according to claim 1, wherein
an element in the first material for generating the metal is more difficult to be oxidized than an element in the second material for generating the oxide.

8. The deposition method according to claim 1, wherein
the second material includes silicon.

9. The deposition method according to claim 1, wherein
the second material includes metal.

10. The deposition method according to claim 9, wherein
the metal in the second material includes at least one of manganese, titan, aluminum, hafnium, tantalum, and strontium.

11. The deposition method according to claim 10, wherein
the second material includes Mn(pmcp)₂.

12. The deposition method according to claim 1, wherein
the first material includes at least one of copper, nickel, and ruthenium.

13. The deposition method according to claim 12, wherein
the first material includes one of Cu(thmd)₂, Cu(acac)₂, and Cu(hfac)₂.

14. The deposition method according to claim 1, further comprising
forming a metal layer on a surface of the compound layer after forming the compound layer.

15. A deposition apparatus for forming a compound layer including a metal and an oxide by a supercritical fluid deposition method, the apparatus comprising
a portion that supplies a first material for generating the metal and a second material for generating the oxide to a supercritical fluid, and
a portion that changes a ratio of a supplied amount of the first material with respect to a supplied amount of the second material.

16. A deposition apparatus for forming a laminated film by stacking a metal layer above an insulating layer on a surface of a substrate through a compound layer including a metal and an oxide, the deposition apparatus comprising
a portion that supplies a supercritical fluid, a first material for generating the metal in the compound layer, and a second material for generating the oxide in the compound layer to the substrate, and
a portion that changes a ratio of a supplied amount of the first material with respect to a supplied amount of the second material.

17. The deposition apparatus according to claim 15, wherein
the portion that changes the ratio of the supplied amount of the first material with respect to the supplied amount of the second material continuously or in a stepwise manner with an increase of a thickness of the compound layer.

18. The deposition apparatus according to claim 15, further comprising
a portion that mixes the supercritical fluid with a reducing agent, wherein
the metal is deposited in the compound layer by reducing the first material with the reducing agent.

19. The deposition apparatus according to claim 18, wherein
the reducing agent is hydrogen.

20. The deposition apparatus according to claim 15, wherein
the supercritical fluid includes an oxidizing agent, and
the oxide is deposited on the compound layer by oxidizing the second material with the oxidizing agent.

21. The deposition apparatus according to claim 15, wherein
an element in the first material for generating the metal is more difficult to be oxidized than an element in the second material for generating the oxide.

22. The deposition apparatus according to claim 15, wherein
the second material includes silicon.

23. The deposition apparatus according to claim 15, wherein
the second material includes metal.

24. The deposition apparatus according to claim 23, wherein
the metal in the second material includes at least one of manganese, titan, aluminum, hafnium, tantalum, and strontium.

25. The deposition apparatus according to claim 24, wherein
the second material includes Mn(pmcp)₂.

26. The deposition apparatus according to claim 15, wherein
the first martial includes at least one of copper, nickel, and ruthenium.

27. The deposition apparatus according to claim 26, wherein
the first material includes one of Cu(thmd)₂, Cu(acac)₂, and Cu(hfac)₂.

28. The deposition apparatus according to claim 15, further comprising
a portion that forms a metal layer on a surface of the compound layer after forming the compound layer.

29. A deposition apparatus for forming a compound layer including a metal and an oxide by a supercritical fluid deposition method, the apparatus comprising
a portion that supplies a first material including a metal particulate or a material for generating a metal particulate and a second material for generating the oxide to a supercritical fluid, and
a portion that changes a ratio of a supplied amount of the first material with respect to a supplied amount of the second material.

30. A deposition apparatus for forming a laminated film by stacking a metal layer above an insulating layer on a surface of a substrate through a compound layer including a metal and an oxide, the deposition apparatus comprising
a portion that supplies a supercritical fluid with a first material including a metal particulate or a material for generating a metal particulate that becomes the metal in the compound layer and a second material for generating the oxide in the compound layer to the substrate, and
a portion that changes a ratio of a supplied amount of the first material with respect to a supplied amount of the second material.

31. The deposition apparatus according to claim 29, wherein
the portion that changes the ratio of the supplied amount of the first material with respect to the supplied amount of the second material continuously or in a stepwise manner with an increase of a thickness of the compound layer.

32. The deposition apparatus according to claim 29, further comprising
a portion that supplies the first material including the material for generating the metal particulate to the supercritical fluid and forms the metal particulate by a thermal reaction in the supercritical fluid.

33. The deposition apparatus according to claim 29, wherein
the supercritical fluid includes an oxidizing agent, and
the oxide is deposited in the compound layer by oxidizing the second material with the oxidizing agent.

34. The deposition apparatus according to claim 29, wherein
the metal particulate is more difficult to be oxidized than an element in the second material for generating the oxide.

35. The deposition apparatus according to claim 29, wherein
the second material includes silicon.

36. The deposition apparatus according to claim 29, wherein
the second material includes metal.

37. The deposition apparatus according to claim 36, wherein
the metal in the second material includes at least one of manganese, titan, aluminum, hafnium, tantalum, and strontium.

38. The deposition apparatus according to claim 37, wherein
the second material includes Mn(pmcp)₂.

39. The deposition apparatus according to claim 29, wherein
the metal particulate includes at least one of copper, nickel, and ruthenium.

40. The deposition apparatus according to claim 39, wherein
the material for generating the metal particulate includes one of Cu(thmd)₂, Cu(acac)₂, and Cu(hfac)₂.

41. The deposition apparatus according to claim 29, further comprising
a portion that forms a metal layer on a surface of the compound layer after forming the compound layer.

42. A laminated film formed on a insulating surface, comprising
a compound layer formed on the insulating surface and including a metal and an oxide, and
a metal layer formed on the compound layer, wherein
a metal concentration of the compound layer increases from a insulating surface side toward a metal layer side.

43. The laminated film according to claim 42, wherein
the metal concentration of the compound layer increases from the insulating surface side toward the metal layer side gradually in a slope manner or in a stepwise manner.

44. The laminated film according to claim 43, wherein
a content of the metal or a content of the oxide in the compound layer changes more than 10% per 10 nm in a thickness direction of the compound layer.

45. The laminated film according to claim 42, wherein
the metal in the compound layer is more difficult to be oxidized than an element that forms the oxide.

46. The laminated film according to claim 42, wherein
the oxide in the compound layer is a metal oxide.

47. The laminated film according to claim 42, wherein
the metal oxide includes one of manganese oxide, titanium oxide, aluminum oxide, hafnium oxide, tantalum oxide, and strontium titanate.

48. The laminated film according to claim 42, wherein
the metal in the compound layer includes at least one of copper, nickel, and ruthenium.

49. The laminated film according to claim 42, wherein
the insulating surface includes at least one of silicon oxide and silicon nitride.

50. The laminated film according to claim 42, wherein
the insulating surface has a three-dimensional structure.

51. The laminated film according to claim 50, wherein
the three-dimensional structure is a trench or a hole having an aspect ratio of higher than or equal to 100.

52. The laminated film according to claim 42, wherein
the metal layer includes at least one of copper and ruthenium.

53. The laminated film according to claim 42, wherein
the oxide in the compound layer is a silicon oxide.
